(19) United States
(12) Patent Application Publication
(10) Pub. No.: US 2022/0156548 A1
(43) Pub. Date: May 19, 2022

(54) System and Method for Improving a Processing System

(71) Applicant: Marvell Asia Pte Ltd, Singapore (SG)

(72) Inventor: William Knox Ladd, Raleigh, NC (US)

(21) Appl. No.: 17/594,150

(22) PCT Filed: Dec. 3, 2020
(86) PCT No.: PCT/US2020/062978

§ 371 Date: Oct. 4, 2021

Related U.S. Application Data
(60) Provisional application No. 62/943,690, filed on Dec. 4, 2019.

(51) Int. Cl. G06N 3/02; G06N 3/12; G06F 12/08

(52) U.S. Cl. CPC G06N 3/02; G06F 12/08; G06N 3/126

(57) ABSTRACT

A system and corresponding method improve a processing system. The system comprises a first learning system coupled to a system controller. The first learning system identifies variations for altering processing of a processing system to meet at least one goal. The system controller applies the variations identified to the processing system. The system further comprises a second learning system coupled to the system controller. The second learning system determines respective effects of the variations identified and applied. The first learning system converges on a given variation of the variations based on the respective effects determined. The given variation enables the at least one goal to be met, improving the processing system, such as by increasing throughput, reducing latency, reducing power consumption, reducing temperature, etc.

### RELATED APPLICATION

This application claims the benefit of U.S. Provisional Application No. 62/943,690, filed on Dec. 4, 2019. The entire teachings of the above application are incorporated herein by reference.

### BACKGROUND

Unlike natural intelligence that is displayed by humans and animals, artificial intelligence (AI) is intelligence demonstrated by machines. Machine learning is a form of AI that enables a system to learn from data, such as sensor data, data from databases, or other data. A focus of machine learning is to automatically learn to recognize complex patterns and make intelligent decisions based on data. Machine learning seeks to build intelligent systems or machines that can learn, automatically, and train themselves based on data, without being explicitly programmed or requiring human intervention. Neural networks, modeled loosely on the human brain, are a means for performing machine learning.

### SUMMARY

According to an example embodiment, a system comprises a first learning system coupled to a system controller. The first learning system is configured to identify variations for altering processing of a processing system to meet at least one goal. The system controller is configured to apply the variations identified to the processing system. The system further comprises a second learning system coupled to the system controller. The second learning system is configured to determine respective effects of the variations identified and applied. The first learning system is further configured to converge on a given variation of the variations based on the respective effects determined. The given variation enables the at least one goal to be met.

The first learning system may be configured to employ a genetic method to identify the variations and the second learning system may be configured to employ a neural network to determine the respective effects.

The at least one goal may be associated with memory utilization, memory latency, throughput, power, or temperature within the system, or combination thereof. It should be understood, however, that that at least one goal is not limited thereto. For example, the at least one goal may be associated with memory provisioning, configuration, or structure. The at least one goal may be measurable, for example, via at least one monitored parameter that may be monitored by at least one monitoring circuit, as disclosed further below. The throughput, power, or temperature may be system or memory throughput, power, or temperature.

The variations identified may alter the processing by altering at least one memory address, memory access order, memory access pattern, or a combination thereof. It should be understood, however, that the variations identified are not limited to altering same.

The processing system may be coupled to a memory system and the variations identified may alter the processing by relocating or invalidating data in a memory system.

The processing system may be coupled to a memory system and the variations identified may alter memory access of the memory system based on a structure of the memory system.

The variations identified may alter an instruction flow, instruction pipeline, clock speed, voltage, idle time, field programmable gate array (FPGA) logic, or combination thereof, of the processing system. It should be understood, however, that the variations identified are not limited to altering same.

The system controller may be further configured to apply the variations identified to the processing system by modifying the processing system or by transmitting at least one message to the processing system which, in turn, is configured to apply the variations identified.

The second learning system may be further configured to employ at least one monitored parameter to determine the respective effects. The respective effects may be associated with memory utilization, temperature, throughput, latency, power, quality of service (QoS), memory access, or combination thereof. It should be understood, however, that the respective effects are not limited to being associated therewith. The throughput, power, or temperature may be system or memory throughput, power, or temperature.

The system may further comprise at least one monitoring circuit configured to produce at least one monitored parameter by monitoring at least one parameter associated with the processing, periodically, over time. The second learning system may be further configured to employ at least one monitored parameter to determine the respective effects.

The variations identified may include populations of respective trial variations. The first learning system may be configured to employ a genetic method to evolve the populations on a population-by-population basis. The first learning system may be further configured to transmit, on the population-by-population basis, the populations evolved to the system controller. To apply the variations identified, the system controller may be further configured to apply the respective trial variations of the populations evolved to the processing system on a trial-variation-by-trial-variation basis.

The second learning system may be configured to employ a neural network. The neural network may be configured to determine the respective effects based on at least one monitored parameter of the processing system, the respective effects resulting from applying the respective trial variations to the processing system. The neural network may be further configured to assign respective rankings to the respective trial variations based on the respective effects determined and the at least one goal. The neural network may be further configured to transmit, to the system controller, the respective rankings on the trial-variation-by-trial-variation basis.

The system controller may be further configured to transmit, to the first learning system, respective ranked populations of the populations. The respective ranked populations may include respective rankings of the respective trial variations. The respective rankings may be assigned by the neural network and transmitted to the system controller. The genetic method may be configured to evolve a present population of the populations into a next population of the populations based on a given respective ranked population of the respective ranked populations, the given respective ranked population corresponding to the present population.

The variations identified may include populations of respective trial variations, wherein the genetic method is configured to evolve the populations on a population-by-population basis. The given variation may be a given trial variation included, consistently, by the genetic method in the populations evolved, and wherein the given variation is converged on by the genetic method based on a respective ranking assigned thereto by the neural network.

The system may further comprise a target system and a trial system. The system controller may be coupled to the target system and to the trial system. The processing system may be a trial processing system of the trial system. The target system may include a target processing system. The trial processing system may be a cycle-accurate model of the target processing system. The system controller may be further configured to apply the given variation to the target processing system.

The target processing system may be a physical system. The cycle-accurate model may be a physical representation or simulated model of the target processing system.

According to another example embodiment, a method may comprise identifying variations for altering processing of a processing system to meet at least one goal, applying the variations identified to the processing system, determining respective effects of the variations identified and applied, and converging on a given variation of the variations identified and applied, the converging based on the respective effects determined, the given variation enabling the at least one goal to be met.

Further alternative method embodiments parallel those described above in connection with the example system embodiment.

According to another example embodiment, a system may comprise means for identifying variations for altering processing of a processing system to meet at least one goal, means for applying the variations identified to the processing system, means for determining respective effects of the variations identified and applied, and means for converging on a given variation of the variations identified and applied. The converging may be based on the respective effects determined. The given variation may enable the at least one goal to be met.

According to another example embodiment, a non-transitory computer-readable medium has encoded thereon a sequence of instructions which, when loaded and executed by at least one processor, causes the at least one processor to identify variations for altering processing of a processing system to meet at least one goal, apply the variations identified to the processing system, determine respective effects of the variations identified and applied, and converge on a given variation of the variations identified and applied, the converging based on the respective effects determined, the given variation enabling the at least one goal to be met.

Alternative non-transitory computer-readable medium embodiments parallel those described above in connection with the example system embodiment.

It should be understood that example embodiments disclosed herein can be implemented in the form of a method, apparatus, system, or computer readable medium with program codes embodied thereon.

### BRIEF DESCRIPTION OF THE DRAWINGS

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1A is a block diagram of an example embodiment of a system with an example embodiment of a learning system implementing a machine learning process (not shown) thereon.

FIG. 1B is a block diagram of an example embodiment of the system of FIG. 1A.

FIG. 2 is a block diagram of an example embodiment of a machine learning process in a system.

FIG. 3 is a block diagram of another example embodiment of a system for altering memory accesses using machine learning.

FIG. 4 is a flow diagram of an example embodiment of a method for altering memory accesses using machine learning.

FIG. 5 is block diagram of an example embodiment of a system or improving a processing system.

FIG. 6 is flow diagram of an example embodiment of a method for improving a processing system.

FIG. 7 is a block diagram of an example internal structure of a computer optionally within an embodiment disclosed herein.

### DETAILED DESCRIPTION

A description of example embodiments follows.

It should be understood that while example embodiments disclosed herein may be described with respect to altering memory accesses to improve a processing system, embodiments disclosed herein are not limited to same and may be employed to alter other aspects of the processing system to effect improvement thereof.

Example embodiments disclose herein employ machine learning to alter (e.g., manipulate) memory accesses to alter aspects, such as performance, latency, or power, as disclosed further below. It should be understood that altering the memory accesses is not limited to altering performance, latency, power, or a combination thereof. Machine learning methods, in accordance with aspects of the present disclosure, may encompass a variety of approaches, including supervised and unsupervised methods. While example embodiments of machine learning methods disclosed herein may be described as employing a genetic method and neural network, it should be understood that additional or alternative machine learning methods may be employed to carry out an example embodiment(s) disclosed herein, such as by using, for example, support vector machines (SVMs), decision trees, Markov models, hidden Markov models, Bayesian networks, cluster-based learning, other learning machine(s), or a combination thereof.

Trying to develop methods to improve a processing system by altering the memory addresses or access patterns thereof can be difficult and will vary over time as well as vary based on the memory access pattern of a given instruction flow. Current solutions including trial-and-error techniques that are manually performed by a user and utilize the user's time and effort to study historical patterns, alter instruction flow to work better with current hardware architecture, etc.

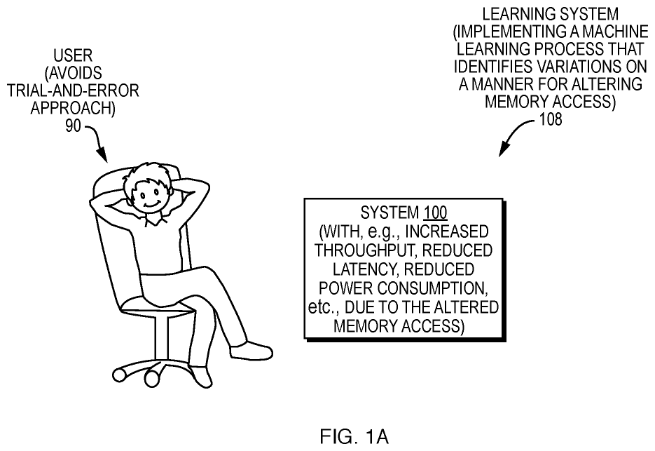

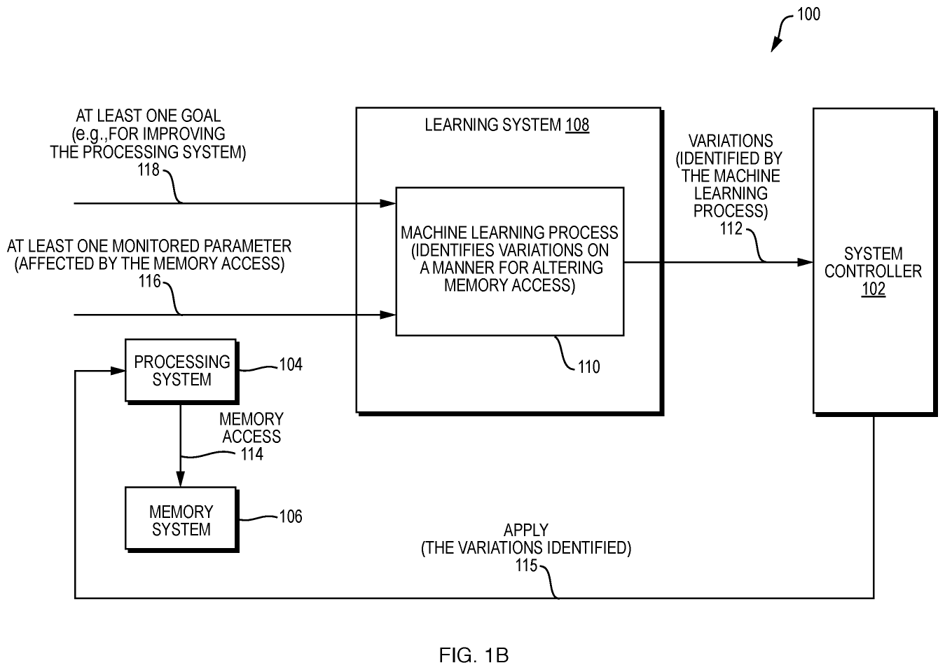

An example embodiment disclosed herein creates a system that uses a machine learning and control system to manipulate the memory address (possibly in different ways for various ranges), manipulate memory access order, or possibly relocate (or invalidate) chunks of memory. Furthermore, the learning system may provide feedback for ways to alter a processing system to meet target goal(s) for optimizing a system incorporating same. Such target goal(s) could be to reduce latency, increase throughput, reduce power consumption, but such target goal(s) are not limited thereto and be or include other goal(s) considered useful for the system to self-optimize around. It can become very difficult for a user to recognize ways to optimize past a small number of variables, while an example embodiment of a machine learning and control system can adapt in real-time and learn to perform complex manipulations that may not be at all obvious to the user, such as disclosed below with regard to FIG. 1A.

FIG. 1A is a block diagram of an example embodiment of a system 100 with an example embodiment of a learning system 108 implementing a machine learning process (not shown) thereon. The learning system 108 identifies, via the machine learning process, variations on a manner for altering memory access of a memory system, such as the memory system 106 accessed by the processing system 104 of FIG. 1B, disclosed further below, in order to meet a goal(s), such as to increase throughput, reduce latency, reduce power consumption, reduce temperature, etc., in the system 100. By employing the machine learning process in the system 100, a user 90 (e.g., software/hardware engineer) can avoid conducting trial-and-error experiments in order to determine ways to alter the memory access in order to meet the goal(s).

For example, the user 90 need not spend time and effort to develop and test methods that alter memory access in order to meet the goal(s). Such methods can be difficult to develop as they may need to vary over time as well as vary based on a memory access pattern of a given instruction flow being executed by the processing system that accesses the memory system. Further, the effectiveness of such methods depends upon the hardware architecture of the system 100 and, thus, the user 90 would need to spend time to customize (and test) for each hardware architecture. Such customization may involve studying historical memory access patterns and altering instruction flow for different hardware architectures in an effort to meet the goal(s) for each of the different hardware architectures. According to the example embodiment, the learning system 108 uses a machine learning process, such as the machine learning process 110 of FIG. 1B, disclosed below, that can adapt in real-time and learn to perform complex manipulations of the memory access that may not be at all obvious to the user 90.

FIG. 1B is a block diagram of an example embodiment of the system 100 of FIG. 1A, disclosed above. In the example embodiment of FIG. 1B, the system 100 comprises a system controller 102 coupled to a processing system 104. The processing system 104 may be an embedded processor system, multi-core processing system, data center, or other processing system. It should be understood, however, that the processing system 104 is not limited thereto. The processing system 104 is coupled to a memory system 106. The memory system 106 includes at least one memory (not shown). The system 100 further comprises the learning system 108 that is coupled to the system controller 102. The learning system 108 may be referred to as a self-modifying learning system that is capable of adapting itself based on effects of applying changes to the processing system 104 in order to meet at least one goal 118, as disclosed further below. The at least one goal 118 may be referred to interchangeably herein as at least one optimization criterion.

The learning system 108 is capable of operating, autonomously, that is, the learning system 108 is free to explore and develop its own understanding of variations (i.e., changes or alterations) to the processing system 104 to enable the at least one goal 118 to be met, absent explicit programming. The learning system 108 is configured to identify, via a machine learning process 110, variations 112 on a manner for altering memory access 114 of the memory system 106 to meet at least one goal 118. The system controller 102 is configured to apply 115 the variations 112 identified to the processing system 104. The machine learning process 110 is configured to employ at least one monitored parameter 116 to converge on a given variation (not shown) of the variations 112 identified and applied. The at least one monitored parameter 116 is affected by the memory access 114. The given variation enables the at least one goal 118 to be met. The at least one monitored parameter 116 may represent memory utilization, memory latency, throughput, power, or temperature within the system 100 that is affected by the memory access 114. The throughput, power, or temperature may be system or memory throughput, power, or temperature.

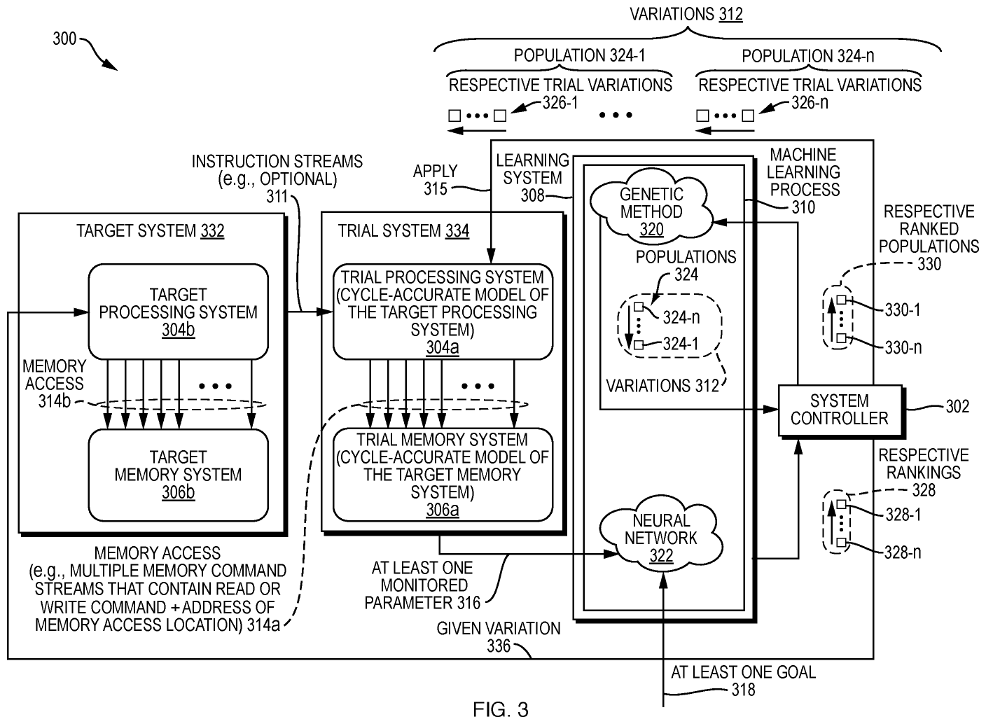

According to an example embodiment, the machine learning process 110 may, independently, explore different ways to perform the altering and, as such, the machine learning process 110 may determine the manner. The at least one goal 118 may be associated with memory utilization, memory latency, throughput, power, or temperature within the system 100, or combination thereof. It should be understood, however, that the at least one goal 118 is not limited thereto. For example, the at least one goal 118 may be associated with memory provisioning, configuration, or structure. The at least one goal may be measurable, for example, via the at least one monitored parameter 116 that may be monitored by at least one monitoring circuit, as disclosed further below. The throughput, power, or temperature may be system or memory throughput, power, or temperature. The manner may include altering at least one memory address, memory access order, memory access pattern, or a combination thereof. It should be understood, however, that the manner is not limited thereto. According to an example embodiment, the memory system 106 may include at least one dynamic random-access memory (DRAM) and the manner may include altering bank access to banks of the at least one DRAM, as disclosed further below with regard to FIG. 3. It should be understood, however, that the manner is not limited thereto.

The variations 112 that are identified may include variations on the at least one memory address, memory access order, memory access pattern, or combination thereof. The at least one memory address, memory access order, memory access pattern, or combination thereof, may be associated with a sequence of instructions (not shown) that are executed by the processing system 104. It should be understood, however, that the variations 112 identified are not limited thereto. The manner may include relocating or invalidating data in the memory system 106. It should be understood, however, that the manner is not limited thereto. The variations 112 that are identified may include variations on the relocating, invalidating, or combination thereof. It should be understood, however, that the variations 112 identified are not limited thereto. The manner for altering the memory access 114 may be based on a structure of the memory system 106, such as disclosed further below with regard to FIG. 3. It should be understood, however, that the manner is not limited to being based on the structure of the memory system 106.

Applying the variations 112 identified to the processing system 104 may include modifying an instruction flow, instruction pipeline, clock speed, voltage, idle time, field programmable gate array (FPGA) logic, or combination thereof, of the processing system 104. It should be understood, however, that the modifying is not limited thereto. The system controller 102 may be further configured to perform the modifying, or to transmit at least one message (not shown) to the processing system 104 which, in turn, is configured to perform the modifying.

The at least one monitored parameter 116 may include memory utilization, temperature, throughput, latency, power, quality of service (QoS), the memory access, or combination thereof. It should be understood, however, that the at least one monitored parameter 116 is not limited thereto. The throughput, power, or temperature may be system or memory throughput, power, or temperature. The system 100 may further comprise at least one monitoring circuit (not shown) that is configured to produce the at least one monitored parameter 116 by monitoring at least one parameter associated with the memory access 106, periodically, over time.

The system 100 may be a physical system or a simulated system model of the physical system. The simulated system model may be cycle-accurate (e.g., on a digital cycle) relative to the physical system. The at least one monitoring circuit may be at least one physical monitoring circuit or at least one simulated monitoring circuit model of the at least one physical monitoring circuit of the physical system or simulated system model, respectively, such as disclosed further below with regard to FIG. 3.

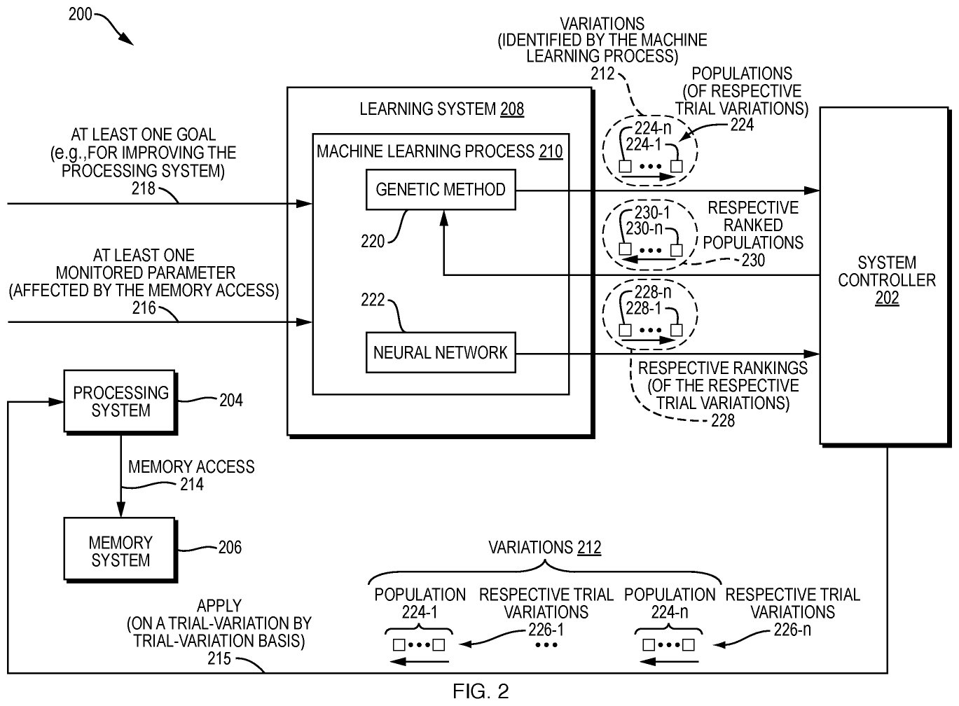

According to an example embodiment, the machine learning process 110 may be configured to employ a genetic method in combination with a neural network, such as the genetic method 220 and neural network 222 (also referred to interchangeably herein as an inference engine) disclosed below with regard to FIG. 2.

FIG. 2 is a block diagram of an example embodiment of a machine learning process 210 in a system 200. The system 200 may be employed as the system 100 of FIGS. 1A and 1B, disclosed above, and, as such, the machine learning process 210 may be employed as the machine learning process 110, disclosed above.

In the example embodiment of FIG. 2, the system 200 comprises a system controller 202 coupled to a processing system 204. The processing system 204 is coupled to a memory system 206. The system 200 further comprises a learning system 208 that is coupled to the system controller 202. The learning system 208 is configured to identify, via the machine learning process 210, variations 212 on a manner for altering memory access 214 of the memory system 206 to meet at least one goal 218.

The system controller 202 is configured to apply 215 the variations 212 identified to the processing system 204. The machine learning process 210 is configured to employ at least one monitored parameter 216 to converge on a given variation (not shown) of the variations 212 identified and applied. The at least one monitored parameter 216 is affected by the memory access 214. The given variation enables the at least one goal 218 to be met.

The machine learning process 210 is configured to employ a genetic method 220 in combination with a neural network 222. The neural network 222 may be at least one neural network, such as a convolutional neural network (CNN), recurrent neural network (RNN), or combination thereof. It should be understood, however, that the neural network 222 is not limited to a CNN, RNN, or combination thereof and can by any suitable artificial neural network (ANN) or combination of neural networks.

According to an example embodiment, the genetic method 220 evolves variations (referred to interchangeably herein as alterations, modifications, or adjustments) for varying the memory access 114 based on a particular manner(s) (e.g., way(s)) for such altering and the neural network 222 determines respective effects of the altering and enables the genetic method 220 to evolve additional variations based on same. According to an example embodiment, the genetic method 220 can evolve the manner into a new manner(s) (e.g., way(s)) for altering the memory access 214.

The variations 212 identified by the genetic method 220 include populations 224 of respective trial variations, such as the initial population 224-1 that includes the respective trial variations 226-1 of the variations 212 identified, and the nth population 224-n that includes the respective trial variations 226-n of the variations 212 identified. The genetic method 220 may be configured to evolve the populations 224 on a population-by-population basis.

Genetic methods, also referred to in the art as genetic algorithms (GAs) may be considered to be stochastic search methods which act on a population of possible solutions to a problem. Genetic methods are loosely based on the mechanics of population genetics and selection. The potential solutions may be considered as encoded as “genes” that are members of solutions produced by “mutating” members of a current population and by combining solutions together to form a new solution. Solutions that are deemed to be “better” (relative to other solutions) are selected to breed and mutate while others, namely those deemed to be “worse” (relative to other solutions), are discarded. Genetic methods can be used to search a space (e.g., populations) of potential solutions to find one which solves the problem being solved. According to an example embodiment, the neural network 222 ranks the effectiveness of proposed solutions generated by the genetic method 220 and the genetic method evolves a next set (e.g., population) of solutions based on same.

According to an example embodiment, the genetic method 220 may modify a present population based on respective rankings (e.g., scores) of its members, that is, its respective trial variations, that are ranked by the neural network 222. The present population may be a most recently applied population that has been applied to the processing system 204 by the system controller 202. The genetic method 220 may be configured to discard a given percentage or number of the respective trial variations of the present population based on the respective rankings, leave a pre-determined number of the respective trial variations unchanged, replicate respective trial variations based on the respective rankings, and add new respective trial variations, thereby evolving the present population into a next population.

For example, the manner (e.g., way) for altering the memory access 214 may include re-arranging the address bits of the address for accessing the memory system 206. It should be understood, however, that the manner is not limited thereto. The genetic method 220 may produce an initial population of respective variations which have a memory address re-arranged, for example, ten times—but not limited thereto, based on a given population size of ten. It should be understood, however, that the given population size is not limited to ten. The respective variations may have the memory address re-arranged, randomly, ten times—but not limited thereto. Further, it should be understood that the memory is not limited to being re-arranged, randomly.

The neural network 222 may rank each of the members of the initial population based on respective effects determined from the at least one monitored parameter 216 and based on the at least one goal 218, following application of the respective variations to the processing system 204. For example, respective variations with respective effects that represent a higher level of meeting the at least one goal 218 may be assigned higher respective rankings relative to respective variations with respective effects of a lesser level. Such assignment of rankings to respective variations produces a ranked population, such as a given ranked population of the respective ranked populations 230 of the populations 224.

The genetic method 220 may take, for example, the top three solutions (but is not limited thereto), that is, the top three highest ranking variations (i.e., members) of the ranked population and discard the remaining members. The genetic method 220 may replicate a highest-ranking member a first number of times, replicate a next highest-ranking member a second number of times, and add new members (e.g., mutated members) to produce a new population of respective variations, the new population having a given population size, that is, a given number of respective members.

The genetic method 220 may iterate to produce new generations to be applied and ranked until a certain member, that is, a given respective variation, is ranked with a given ranking, consistently, for example, a given number of times, across the generations of populations 224 at which point, the genetic method 220 is understood to have converged on the given respective variation, such as the given variation 336 of FIG. 3, disclosed further below. It should be understood that the genetic method 220 is not limited to evolving the populations 224 as disclosed herein.

The learning system 208 may be further configured to transmit, on the population-by-population basis, the populations 224 evolved to the system controller 202. To apply the variations 212 identified, the system controller 202 may be further configured to apply 215 the respective trial variations (e.g., 224-1 . . . 224-n) of the populations 224 evolved to the processing system 204 on a trial-variation-by-trial-variation basis.

The neural network 222 may be configured to determine, based on the at least one monitored parameter 216, respective effects (not shown) of applying the respective trial variations (e.g., 224-1 . . . 224-n) to the processing system 204. The neural network 222 may be further configured to assign respective rankings 228 to the respective trial variations (e.g., 224-1 . . . 224-n) based on the respective effects determined and the at least one goal 218. The neural network 222 may be further configured to transmit, to the system controller 202, the respective rankings 228 on the trial-variation-by-trial-variation basis.

The system controller 202 may be further configured to transmit, to the learning system 208, respective ranked populations 230 of the populations 224. The respective ranked populations 230 include respective rankings of the respective trial variations, that is, the members of the respective population. For example, the respective rankings 228 include the respective rankings 228-1 for the respective trial variations 226-1 of the population 224-1. Similarly, the respective rankings 228 include the respective rankings 228-n for the respective trial variations 226-n of the population 224-n. The respective rankings 228 may be assigned by the neural network 222 and transmitted to the system controller 202.

The genetic method 220 may be configured to evolve a present population (e.g., 224-n) of the populations 224 into a next population (e.g., 224-(n+1)—(not shown)) of the populations 224 based on a given respective ranked population 230-n of the respective ranked populations 230, wherein the given respective ranked population 230-n corresponds to the present population (e.g., 224-n).

Aside from the initial population (e.g., 224-1), each population of the populations 224 is evolved from a previous population. According to an example embodiment, the initial population may be generated such that it includes respective trial variations that are random variations on the manner. It should be understood, however, that the initial population is not limited to being generated with random variations. Since each population following the initial population is evolved from the previous population, the populations 224 may be referred to as generations of populations, wherein respective trial variations of a given generation are evolved based on respective trial variations of a prior population. As such, the genetic method 220 is configured to evolve the populations 224 on a population-by-population basis.

According to an example embodiment, the given variation is a given trial variation that is included, consistently, by the genetic method 220 in the populations 224 evolved. The given variation may be converged on by the genetic method 220 based on a respective ranking assigned thereto by the neural network 222. According to an example embodiment, the given variation is applied to a target system, such as the given variation 336 that is applied to the target system 332 of FIG. 3, disclosed below.

FIG. 3 is a block diagram of another example embodiment of a system 300 for altering memory accesses using machine learning. The system 300 may be employed as the system 100 of FIGS. 1A and 1B or the system 200 of FIG. 2, disclosed above. The system 300 comprises a target system 332 and a trial system 334. According to an example embodiment, the trial system 334 is a test system. The trial system 334 alters memory access 314a in the trial system 334 in order to determine a way(s) to alter memory access 314b in the target system 332 to meet at least one goal 318 without affecting operation of the target system 332 for such determination. The memory access 314a of trial system 334 is cycle-accurate relative to the memory access 314b of the target system 332. The memory access 314a and memory access 314b may represent multiple command streams that contain read or write commands in combination with a respective address of a memory access location.

According to an example embodiment, and without limitation, the at least one goal 318 may be to raise dynamic random-access memory (DRAM) utilization of DRAM in a target memory system 306b of the target system 332. For example, the at least one goal 318 may include a given goal to spread such utilization across multiple banks of the DRAM such that threads/cores of a target processing system 304b accessing same does not continuously hit (i.e., access) the same bank, and bank utilization is evenly distributed among the banks of the DRAM. The utilization may be measured, for example, by a monitoring circuit (not shown) that is configured to monitor a percentage of idle cycles of data lanes (e.g., DQ lanes) and communicate such percentage to the neural network 322, periodically, over time.

As such, the manner for altering the memory access 314b of the target memory system 306b may be based on a structure (e.g., banks) of the target memory system 306b. A given monitored parameter (not shown) of at least one monitored parameter 316 may represent such utilization. It should be understood, however, that the at least one monitored parameter 316 is not limited thereto. According to an example embodiment, the target processing system 304b includes at least one processor (not shown) and the target memory system 306b includes a plurality of memories that may be accessed by threads (not shown) that are executing on the target processing system 304b and, thus, are executing on the trial processing system 304a.

Another goal of the at least one goal 318 may be to maintain or improve average latency in the target processing system 304b. Such average latency may be measured, such as by measuring stall time of thread(s) incurred while waiting for data from the target memory system 306b, and the system 300 includes at least one monitored parameter 316 that may reflect same as measured in the trial system 334. It should be understood, however, the at least one goal 318 is not limited to goal(s) disclosed herein and that the at least one monitored parameter 316 is not limited to monitored parameter(s) disclosed herein. According to the example embodiment, the trial system 334 may be employed to determine an optimal way to alter the memory access 314b in the target system 332 to meet the at least one goal 318.

The trial system 334 is a cycle-accurate representation of the target system 332, where the target system 332 may be referred to as the “real” system that is a physical system. As such, the target processing system 304b and target memory system 306b of the target system 332 are physical systems. The target system 332 may be deployed in the field and may be “in-service,” whereas the trial system 334 is a test system and considered to be an “out-of-service” system. According to an example embodiment, the trial system 334 may be a duplicate system of the target system. It should be understood, however, that the trial system 334 is not limited thereto. The trial system 334 includes a trial processing system 304a that is a first cycle-accurate model of the target processing system 306b. The trial system 334 further includes a trial memory system 306a that is a second cycle-accurate model of the target memory system 306b of the target system 332.

The first and second cycle-accurate models may be physical models or simulated models of the target processing system 304b and target memory system 306b, respectively. According to an example embodiment, instructions streams 311 representing the instruction flow of the target processing system 304b may, optionally, be transmitted to the trial processing system 304a to further ensure that the trial system 334 is cycle-accurate relative to the target system 332. According to the example embodiment, the trial system 334 is modeling the target system 332 in real-time and may be referred to interchangeably herein as a shadow system of the target system 332.

In the example embodiment of FIG. 3, the system comprises a system controller 302 coupled to the target system 332 and the trial system 334. The trial system 334 includes the trial processing system 304a coupled to the trial memory system 306a and the target system 334b includes the trial processing system 304b coupled to a trial memory system 306b. According to an example embodiment, the processing system 104 and 204 of FIG. 1B and FIG. 2, disclosed above, correspond to the trial processing system 304a and trial memory system 306a of the trial system 334 of FIG. 3. According to an example embodiment, the given variation disclosed above with regard to FIG. 1B and FIG. 2, may be the given variation 336 of FIG. 3, disclosed below.

The system 300 of FIG. 3 further comprises a learning system 308 that is coupled to the system controller 302. The learning system 308 may be employed as the learning system 108 and 208 of FIG. 1B and FIG. 2, disclosed above. The learning system 308 is configured to identify, via a machine learning process 310, variations 312 on a manner for altering the memory access 314a of the trial memory system 306a to meet the at least one goal 318. According to the example embodiment, the machine learning process 310 is configured to employ a genetic method 320 in combination with a neural network 322, as disclosed in detail further below. The system controller 302 acts on output from the neural network 322, such as the respective rankings 328, disclosed further below, and causes (e.g., initiates) a new population of trial variations to be generated by the genetic method 320.

The new population may be an initial population or generation n+1 population of respective trial variations to be applied by the system controller 302 to the trial processing system 304a. The initial population may be initiated, for example, via a command (not shown) transmitted by the system controller 302 to the learning system 308. The generation n+1 population may be initiated by the system controller 302, for example, by transmitting a respective ranked population of a generation n population. The genetic method 320 may employ the ranked generation n population to evolve the generation n+1 population therefrom. The ranked generation n population represents a present population that has had its respective trial variations (i.e., population members) applied to the trial processing system 304a by the system controller 302 and had its population members ranked by the neural network 322 based on effects of such application reflected by the at least one monitored parameter 316.

According to an example embodiment, the neural network 322 employs the at least one monitored parameter 316 to determine a respective effect of applying a respective trial variation of the variations 312 to the trial processing system 304a. The variations 312 include populations 324 with respective trial variations for varying the memory access 314a. For example, the respective trial variations may be trials of new address hash or address bit arrangements to be tried (applied) in the trial system 334 for accessing the trial memory system 306a. It should be understood, however, that the respective trial variations are not limited thereto.

The new hash or address bit arrangements may be determined by the genetic method 320 that can operate autonomously, that is, the genetic method 320 is free to operate and try different ways to alter the memory access. According to an example embodiment, the neural network 322 has been trained to recognize what is a change (i.e., variation or alteration) to the memory access 314a that is not just transient (although it could still be made somewhat temporary) and should be made to the “real” system, that is, the target system 332, to enable the at least one goal 318 to be met by the target system 332.

The neural network 322 may have been further trained to recognize whether a respective effect of the change is profound enough to perform in-service, or whether the target system 332 should be temporarily halted and reconfigured to have the given variation 336 applied thereto. Such training of the neural network 322 may be performed, at least in part, in a laboratory environment with user driven data (not shown) from a user, such as the user 90 of FIG. 1A, disclosed above. Such user driven data may be captured, over time, using specialized monitored circuits designed to monitor specific parameters of the trial system 334, such as memory utilization, temperature, throughput, latency, power, quality of service (QoS), the memory access, etc., and the user may label such captured data with respective labels that indicate whether a given goal(s) of the at least one goal 318, such as memory utilization, memory latency, throughput, power, temperature, etc., has been met or degree to which the at least one goal 318 has been met. Thus, the neural network 322 has been trained to understand the at least one goal 318. The throughput, power, or temperature may be system or memory throughput, power, or temperature.

The neural network 322 may be employed instead of a method because the neural network 322 is able to recognize, via the at least one monitoring parameter 316, the effects over time of applying the changes (i.e., trial variations) altering the memory access and the neural network 322 is further able to filter out events, such as spikes or thrashing, represented by the effects are deemed to be temporary and, thus, not a viable improvement. As such, the neural network 322 is well suited for ranking the trial variations that have been applied.

The neural network 322 may be static or dynamic. For example, the neural network 322 may be trained, initially, and remain static. Alternatively, the neural network 322 may adapt itself, over time, such as by adding/removing/modifying layers (not shown) of nodes (not shown) based on the effects determined via the at least one monitored parameter 316 correlated with the respective trial variations produced by the genetic method 320 that, once applied, caused such effects.

The memory access 314a is cycle-accurate relative to the memory access 314b of the target memory system 306b. The system controller 302 is configured to apply 315 the variations 312 identified to the trial processing system 304a. The machine learning process 310 is configured to employ the at least one monitored parameter 316 to converge on the given variation 336 of the variations 312 identified and applied, such as disclosed above with regard to FIG. 2. The at least one monitored parameter 316 is affected by the memory access 314a.

The given variation 336 may be a particular variation among all of the variations 312 that enables the at least one goal 318 to be met in the trial system 334 and, thus, in the target system 332. The trial system 334 is a cycle-accurate representation of the target system 332 and, as such, since the given variation 336 enables the at least one goal 318 to be met by the trial system 334, the given variation 336 may then be applied to the target processing system 304b, enabling the at least one goal 318 to be met by the target system 332. Service of the target system 332 is, however, unaffected by the machine learning process 310 utilized to determine the given variation 336 that enables the at least one goal 318 to be met.

In the example embodiment of FIG. 3, the variations 312 that are identified include populations 324 of respective trial variations, such as the initial population 324-1 that includes the respective trial variations 326-1 of the variations 312 identified, and the nth population 324-n that includes the respective trial variations 326-n of the variations 312 identified. The genetic method 320 is configured to evolve the populations 324 on a population-by-population basis.

The learning system 308 is further configured to transmit, on the population-by-population basis, the populations 324 evolved to the system controller 302. To apply 315 the variations 312 identified, the system controller 302 is further configured to apply 315 the respective trial variations (e.g., 326-1 . . . 326-n) of the populations 324 (e.g., 324-1 . . . 324-n) evolved to the processing system 304 on a trial-variation-by-trial-variation basis.

The neural network 322 is configured to determine, based on the at least one monitored parameter 316, respective effects (not shown) of applying the respective trial variations (e.g., 324-1 . . . 324-n) to the trial processing system 304a. The neural network 322 is further configured to assign respective rankings 328 to the respective trial variations (e.g., 324-1 . . . 324-n) based on the respective effects determined and the at least one goal 318. The neural network 322 may be further configured to transmit, to the system controller 302, the respective rankings 328 on the trial-variation-by-trial-variation basis.

The system controller 302 is further configured to transmit, to the learning system 308, respective ranked populations 330 of the populations 324. The respective ranked populations 330 include respective rankings of the respective trial variations, that is, respective rankings of the members (trial variations) of the respective population. For example, the respective rankings 328 include the respective rankings 328-1 for the respective trial variations 326-1 of the population 324-1. Similarly, the respective rankings 328 include the respective rankings 328-n for the respective trial variations 326-n of the population 324-n. The respective rankings 328 may be assigned by the neural network 322 and transmitted to the system controller 302.

The genetic method 320 is configured to evolve a present population (e.g., 324-n) of the populations 324 into a next population (e.g., 324-(n+1)—(not shown)) of the populations 324 based on a given respective ranked population 330-n of the respective ranked populations 330, wherein the given respective ranked population 330-n corresponds to the present population (e.g., 324-n).

Aside from the initial population (e.g., 324-1), each population of the populations 324 is evolved from a previous population. According to an example embodiment, the initial population may be generated such that it includes respective trial variations that are random variations on the manner. It should be understood, however, that the initial population is not limited to being generated with random variations. Since each population following the initial population is evolved from the previous population, the populations 324 may be referred to as generations of populations, wherein respective trial variations of a given generation are evolved based on respective trial variations of a prior population. As such, the genetic method 320 is configured to evolve the populations 324 on a population-by-population basis.

According to an example embodiment, the given variation 336 is a given trial variation that is included, consistently, by the genetic method 320 in the populations 324 evolved, and assigned a consistent ranking by the neural network 322. The given variation 336 is converged on by the genetic method 320 based on a respective ranking assigned thereto by the neural network 322, such as disclosed above with regard to FIG. 2. The system controller 302 is further configured to apply the given variation 336 to the target processing system 304b, thereby enabling the at least one goal 318 to be met in the target system 332.

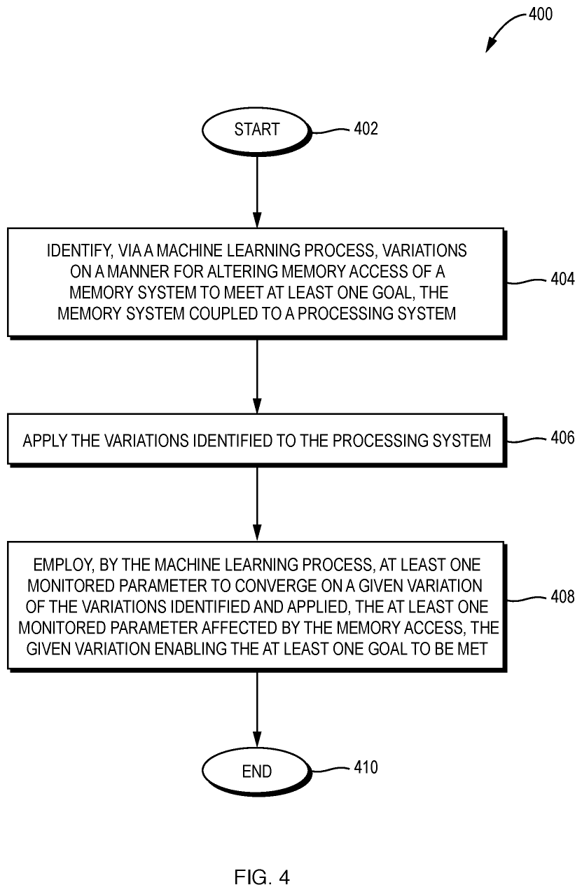

FIG. 4 is a flow diagram 400 of an example embodiment of a method for altering memory accesses using machine learning. The method begins (402) and identifies, via a machine learning process, variations on a manner for altering memory access of a memory system to meet at least one goal, the memory system coupled to a processing system (404). The method applies the variations identified to the processing system (406). The method employs, by the machine learning process, at least one monitored parameter to converge on a given variation of the variations identified and applied, the at least one monitored parameter affected by the memory access, the given variation enabling the at least one goal to be met (408). The method thereafter ends (410) in the example embodiment.

The manner may include altering at least one memory address, memory access order, memory access pattern, or combination thereof. The variations identified may include variations on the at least one memory address, memory access order, memory access pattern, or combination thereof. The manner may include relocating or invalidating data in the memory system. The variations identified may include variations on the relocating, invalidating, or combination thereof. The manner for altering the memory access may be based on a structure of the memory system.

Applying the variations identified to the processing system may include modifying an instruction flow, instruction pipeline (e.g., add or modification an instruction(s)), clock speed, voltage, idle time, field programmable gate array (FPGA) logic (e.g., add a lookup table (LUT) to added acceleration or other modification), or combination thereof, of the processing system.

The method may further comprise producing the at least one monitored parameter by monitoring at least one parameter associated with the memory access, periodically, over time. The at least one monitored parameter may include memory utilization, temperature, throughput, latency, power, quality of service (QoS), the memory access, or combination thereof. It should be understood, however, that the at least one monitored parameter is not limited thereto. The throughput, power, or temperature may be system or memory throughput, power, or temperature.

The method may further comprise implementing the machine learning process using a genetic method in combination with a neural network.

The variations identified may include populations of trial variations and the method may further comprise evolving, by the genetic method, the populations on a population-by-population basis. The method may further comprise transmitting, on the population-by-population basis, the populations evolved. Applying the variations identified may include applying the trial variations of the populations evolved. The applying may be performed on a trial-variation-by-trial-variation basis.

The method may further comprise determining, by the neural network, based on the at least one monitored parameter, respective effects of applying the trial variations to the processing system. The method may further comprise assigning, by the neural network, respective rankings to the trial variations based on the respective effects determined and the at least one goal. The method may further comprise transmitting, by the neural network, the respective rankings on the trial-variation-by-trial-variation basis to a system controller.

The method may further comprise transmitting, by the system controller to a learning system implementing the machine learning process, respective ranked populations of the populations. The respective ranked populations may include respective rankings of the respective trial variations. The respective rankings may be assigned by the neural network and transmitted to the system controller. The method may further comprise evolving, by the genetic method, a present population of the populations into a next population of the populations based on a given respective ranked population of the respective ranked populations, the given respective ranked population corresponding to the present population.

The variations identified may include populations of trial variations and the method may further comprise evolving the populations by the genetic method on a population-by-population basis. The given variation may be a given trial variation included, consistently, by the genetic method in the populations evolved. The method may further comprise converging, by the genetic method, on the given variation based on a respective ranking assigned thereto by the neural network.

The processing system may be a trial processing system of a trial system. The memory system may be a trial memory system of the trial system. The trial processing system may be a first cycle-accurate model of a target processing system of a target system. The trial memory system may be a second cycle-accurate model of a target memory system of the trial system. The method may further comprise applying the given variation to the target processing system of the target system.

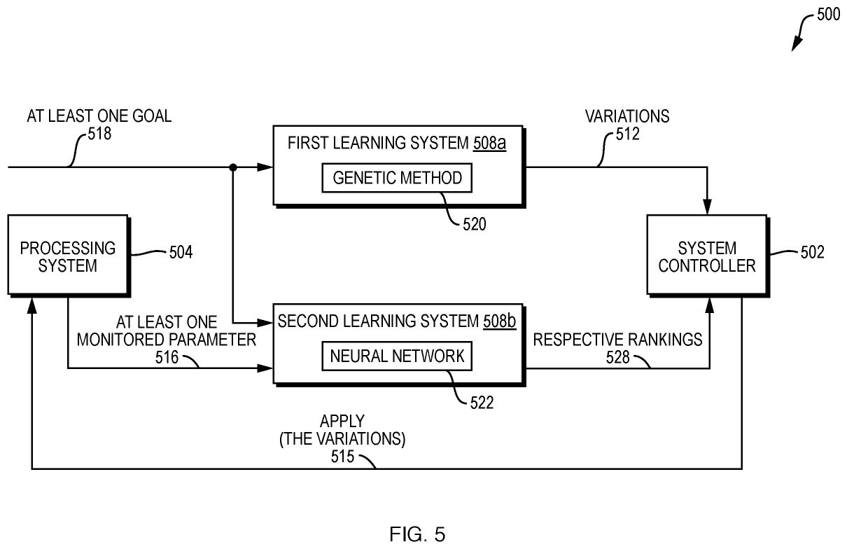

FIG. 5 is block diagram of an example embodiment of a system 500 for improving a processing system 504. The system 500 comprises a first learning system 508a that is coupled to a system controller 502. The first learning system 508a is configured to identify variations 512 for altering processing of the processing system 504 to meet at least one goal 518 518. The system controller 502 is configured to apply 515 the variations 512 identified to the processing system 504. The system 500 further comprises a second learning system 508b that is coupled to the system controller 502. The second learning system 508b is configured to determine respective effects (not shown) of the variations 512 identified and applied. The first learning system 508a is further configured to converge on a given variation (not shown) of the variations 512 based on the respective effects determined. The given variation enables the at least one goal 518 518 to be met.

The first learning system 508a may be configured to employ a genetic method 520 to identify the variations 512 and the second learning system 508b may be configured to employ a neural network 522 to determine the respective effects.

The at least one goal 518 may be associated with memory utilization, memory latency, throughput, power, or temperature within the system 500, or combination thereof. It should be understood, however, that that at least one goal 518 is not limited thereto. For example, the at least one goal 518 may be associated with memory provisioning, configuration, or structure. The throughput, power, or temperature may be system or memory throughput, power, or temperature.

The variations 512 identified may alter the processing by altering at least one memory address, memory access order, memory access pattern, or a combination thereof. It should be understood, however, that the variations 512 identified are not limited to altering same.

The processing system 504 may be coupled to a memory system, such as disclosed above with regard to FIG. 1B, FIG. 2, and FIG. 3, and the variations 512 identified may alter the processing by relocating or invalidating data in a memory system. The variations 512 identified may alter memory access of the memory system based on a structure of the memory system, such as disclosed above with regard to FIG. 3.

The variations 512 identified may alter an instruction flow, instruction pipeline, clock speed, voltage, idle time, field programmable gate array (FPGA) logic, or combination thereof, of the processing system 504. It should be understood, however, that the variations 512 identified are not limited to altering same.

The system controller 502 may be further configured to apply the variations 512 identified to the processing system 504 by modifying the processing system 504 or by transmitting at least one message (not shown) to the processing system 504 which, in turn, is configured to apply the variations 512 identified.

The second learning system 508b may be further configured to employ at least one monitored parameter 516 to determine the respective effects. The respective effects may be associated with memory utilization, temperature, throughput, latency, power, quality of service (QoS), memory access, or combination thereof. It should be understood, however, that the respective effects are not limited to being associated therewith. The throughput, power, or temperature may be system or memory throughput, power, or temperature.

The system 500 may further comprise at least one monitoring circuit (not shown) that is configured to produce the at least one monitored parameter 516 by monitoring at least one parameter associated with the processing, periodically, over time. The second learning system 508b may be further configured to employ the at least one monitored parameter 516 to determine the respective effects.

The variations 512 identified may include populations of respective trial variations, such as disclosed above with regard to FIG. 2. The first learning system 508a may be configured to employ a genetic method 520 to evolve the populations on a population-by-population basis, such as disclosed above with regard to FIG. 2. The first learning system 508a may be further configured to transmit, on the population-by-population basis, the populations evolved to the system controller 502. To apply the variations 512 identified, the system controller 502 may be further configured to apply the respective trial variations of the populations evolved to the processing system 504 on a trial-variation-by-trial-variation basis.

The second learning system 508b may be configured to employ a neural network 522. The neural network 522 may be configured to determine the respective effects based on the at least one monitored parameter 516 of the processing system 504, the respective effects resulting from applying the respective trial variations to the processing system 504. The neural network 522 may be further configured to assign respective rankings 528 to the respective trial variations based on the respective effects determined and the at least one goal 518, such as disclosed above with regard to FIG. 2. The neural network 522 may be further configured to transmit, to the system controller 502, the respective rankings 528 on the trial-variation-by-trial-variation basis.

The system controller 502 may be further configured to transmit, to the first learning system 508a, respective ranked populations (not shown) of the populations (not shown), such as disclosed above with regard to FIG. 2. The respective ranked populations may include respective rankings 528 of the respective trial variations. The respective rankings 528 may be assigned by the neural network 522 and transmitted to the system controller 502. The genetic method 520 may be configured to evolve a present population of the populations into a next population of the populations based on a given respective ranked population of the respective ranked populations, the given respective ranked population corresponding to the present population, such as disclosed above with regard to FIG. 2.

The variations 512 identified may include populations (not shown) of respective trial variations (not shown), wherein the genetic method 520 is configured to evolve the populations on a population-by-population basis, such as disclosed above with regard to FIG. 2. The given variation may be a given trial variation included, consistently, by the genetic method 520 in the populations evolved. The given variation may be converged on by the genetic method 520 based on a respective ranking assigned thereto by the neural network 522, such as disclosed above with regard to FIG. 2.

The system 500 may further comprise a target system (not shown) and a trial system (not shown), such as disclosed above with regard to FIG. 3. The system controller 502 may be coupled to the target system and to the trial system. The processing system 504 may be a trial processing system of the trial system. The target system may include a target processing system. The trial processing system may be a cycle-accurate model of the target processing system, such as disclosed above with regard to FIG. 3. The system controller 502 may be further configured to apply the given variation to the target processing system.

The target processing system may be a physical system. The cycle-accurate model may be a physical representation or simulated model of the target processing system.

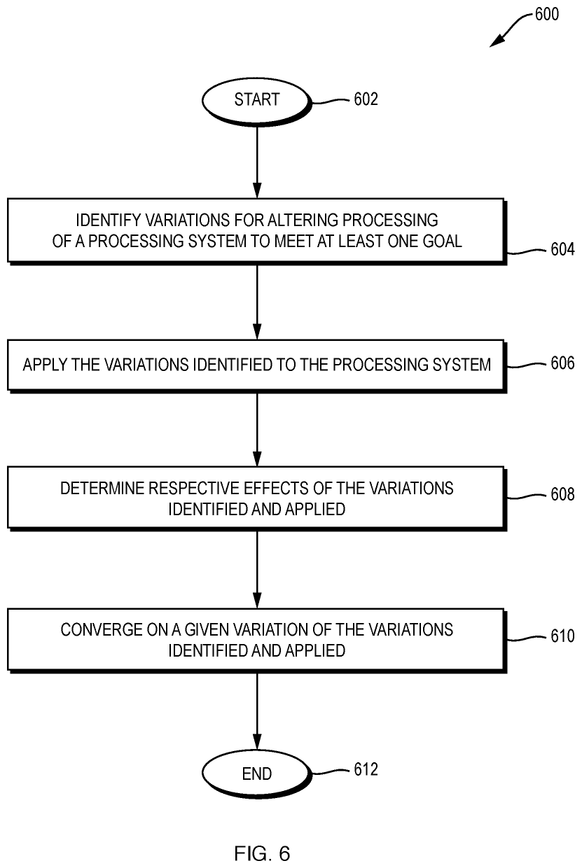

FIG. 6 is flow diagram 600 of an example embodiment of a method for improving a processing system, such as any of the processing systems disclosed above. The method begins (602) and identifying variations for altering processing of the processing system to meet at least one goal (604). The method applies the variations identified to the processing system (606). The method determines respective effects of the variations identified and applied (608). The method converges on a given variation of the variations identified and applied, the converging based on the respective effects determined, the given variation enabling the at least one goal to be met (610). The method thereafter ends (612) in the example embodiment.

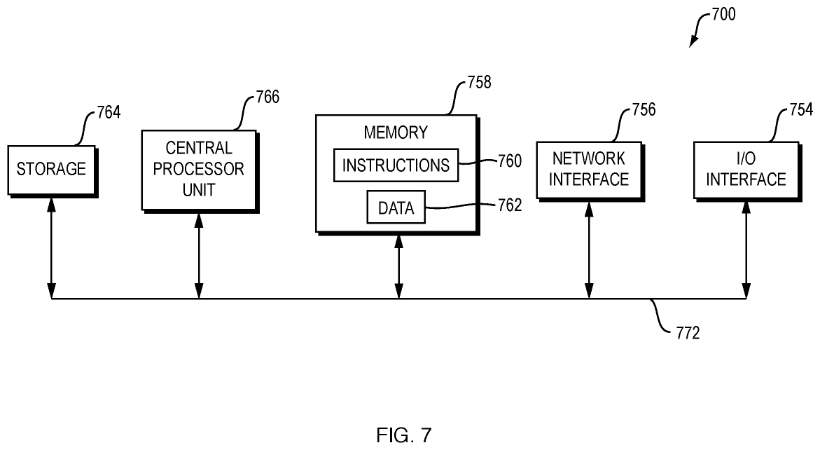

FIG. 7 is a block diagram of an example of the internal structure of a computer 700 in which various embodiments of the present disclosure may be implemented. The computer 700 contains a system bus 752, where a bus is a set of hardware lines used for data transfer among the components of a computer or digital processing system. The system bus 752 is essentially a shared conduit that connects different elements of a computer system (e.g., processor, disk storage, memory, input/output ports, network ports, etc.) that enables the transfer of information between the elements. Coupled to the system bus 752 is an I/O device interface 754 for connecting various input and output devices (e.g., keyboard, mouse, displays, printers, speakers, etc.) to the computer 700. A network interface 756 allows the computer 700 to connect to various other devices attached to a network (e.g., global computer network, wide area network, local area network, etc.). Memory 758 provides volatile or non-volatile storage for computer software instructions 760 and data 762 that may be used to implement embodiments of the present disclosure, where the volatile and non-volatile memories are examples of non-transitory media. Disk storage 764 provides non-volatile storage for computer software instructions 760 and data 762 that may be used to implement embodiments of the present disclosure. A central processor unit 766 is also coupled to the system bus 752 and provides for the execution of computer instructions.

As used herein, the term “engine” may refer to any hardware, software, firmware, electronic control component, processing logic, and/or processor device, individually or in any combination, including without limitation: an application specific integrated circuit (ASIC), a field-programmable gate-array (FPGA), an electronic circuit, a processor and memory that executes one or more software or firmware programs, and/or other suitable components that provide the described functionality.

Example embodiments disclosed herein may be configured using a computer program product; for example, controls may be programmed in software for implementing example embodiments. Further example embodiments may include a non-transitory computer-readable medium containing instructions that may be executed by a processor, and, when loaded and executed, cause the processor to complete methods described herein. It should be understood that elements of the block and flow diagrams may be implemented in software or hardware, such as via one or more arrangements of circuitry of FIG. 7, disclosed above, or equivalents thereof, firmware, a combination thereof, or other similar implementation determined in the future.

In addition, the elements of the block and flow diagrams described herein may be combined or divided in any manner in software, hardware, or firmware. If implemented in software, the software may be written in any language that can support the example embodiments disclosed herein. The software may be stored in any form of computer readable medium, such as random access memory (RAM), read only memory (ROM), compact disk read-only memory (CD-ROM), and so forth. In operation, a general purpose or application-specific processor or processing core loads and executes software in a manner well understood in the art. It should be understood further that the block and flow diagrams may include more or fewer elements, be arranged or oriented differently, or be represented differently. It should be understood that implementation may dictate the block, flow, and/or network diagrams and the number of block and flow diagrams illustrating the execution of embodiments disclosed herein.

The teachings of all patents, published applications and references cited herein are incorporated by reference in their entirety.

While example embodiments have been particularly shown and described, it will be understood by those skilled in the art that various changes in form and details may be made therein without departing from the scope of the embodiments encompassed by the appended claims.

What is claimed is:

1. A system comprising:
a first learning system coupled to a system controller and configured to identify variations for altering processing of a processing system to meet at least one goal, the system controller configured to apply the variations identified to the processing system; and
a second learning system coupled to the system controller, the second learning system configured to determine respective effects of the variations identified and applied, the first learning system further configured to converge on a given variation of the variations based on the respective effects determined, the given variation enabling the at least one goal to be met.

2. The system of claim 1, wherein the first learning system is configured to employ a genetic method to identify the variations and wherein the second learning system is configured to employ a neural network to determine the respective effects.

3. The system of claim 1, wherein the at least one goal is associated with memory utilization, memory latency, throughput, power, or temperature within the system, or combination thereof.

4. The system of claim 1, wherein the variations identified alter the processing by altering at least one memory address, memory access order, memory access pattern, or a combination thereof.

5. The system of claim 1, wherein the processing system is coupled to a memory system and wherein the variations identified alter the processing by relocating or invalidating data in a memory system.

6. The system of claim 1, wherein the processing system is coupled to a memory system and wherein the variations identified alter memory access of the memory system based on a structure of the memory system.

7. The system of claim 1, wherein the variations identified alter an instruction flow, instruction pipeline, clock speed, voltage, idle time, field programmable gate array (FPGA) logic, or combination thereof, of the processing system.

8. The system of claim 1, wherein the system controller is further configured to apply the variations identified to the processing system by modifying the processing system or by transmitting at least one message to the processing system which, in turn, is configured to apply the variations identified.

9. The system of claim 1, wherein the second learning system is further configured to employ at least one monitored parameter to determine the respective effects and wherein the respective effects are associated with memory utilization, temperature, throughput, latency, power, quality of service (QoS), memory access, or combination thereof.

10. The system of claim 1, further comprising at least one monitoring circuit configured to produce at least one monitored parameter by monitoring at least one parameter associated with the processing, periodically, over time, and wherein the second learning system is further configured to employ at least one monitored parameter to determine the respective effects.

11. The system of claim 1, wherein the variations identified include populations of respective trial variations, wherein the first learning system is configured to employ a genetic method to evolve the populations on a population-by-population basis, wherein the first learning system is further configured to transmit, on the population-by-population basis, the populations evolved to the system controller, and wherein, to apply the variations identified, the system controller is further configured to apply the respective trial variations of the populations evolved to the processing system on a trial-variation-by-trial-variation basis.

12. The system of claim 11, wherein second learning system is configured to employ a neural network and wherein the neural network is configured to:
determine the respective effects based on at least one monitored parameter of the processing system, the respective effects resulting from applying the respective trial variations to the processing system;
assign respective rankings to the respective trial variations based on the respective effects determined and the at least one goal; and
transmit, to the system controller, the respective rankings on the trial-variation-by-trial-variation basis.

13. The system of claim 12, wherein:
the system controller is further configured to transmit, to the first learning system, respective ranked populations of the populations, the respective ranked populations including respective rankings of the respective trial variations, the respective rankings assigned by the neural network and transmitted to the system controller; and
the genetic method is configured to evolve a present population of the populations into a next population of the populations based on a given respective ranked population of the respective ranked populations, the given respective ranked population corresponding to the present population.

14. The system of claim 12, wherein the variations identified include populations of respective trial variations, wherein the genetic method is configured to evolve the populations on a population-by-population basis, wherein the given variation is a given trial variation included, consistently, by the genetic method in the populations evolved, and wherein the given variation is converged on by the genetic method based on a respective ranking assigned thereto by the neural network.

15. The system of claim 1, further comprising a target system and a trial system and wherein:
the system controller is coupled to the target system and to the trial system;
the processing system is a trial processing system of the trial system;
the target system includes a target processing system;
the trial processing system is a cycle-accurate model of the target processing system; and
the system controller is further configured to apply the given variation to the target processing system.

16. The system of claim 15, wherein:
the target processing system is a physical system; and
the cycle-accurate model is a physical representation or simulated model of the target processing system.

17. A method comprising:
identifying variations for altering processing of a processing system to meet at least one goal;
applying the variations identified to the processing system;
determining respective effects of the variations identified and applied; and
converging on a given variation of the variations identified and applied, the converging based on the respective effects determined, the given variation enabling the at least one goal to be met.

18. The method of claim 17, further comprising:
employing a genetic method to identify the variations; and
employing a neural network to determine the respective effects of applying the variations identified by the genetic method.

19. The method of claim 17, wherein the at least one goal is associated with memory utilization, memory latency, throughput, power, or temperature within the system, or combination thereof.

20. The method of claim 17, wherein the variations identified alter the processing by altering at least one memory address, memory access order, memory access pattern, or a combination thereof.

21. The method of claim 17, wherein the processing system is coupled to a memory system and wherein the variations identified alter the processing by relocating or invalidating data in a memory system.

22. The method of claim 17, wherein the processing system is coupled to a memory system and wherein the variations identified alter memory access of the memory system based on a structure of the memory system.

23. The method of claim 17, wherein the variations identified alter an instruction flow, instruction pipeline, clock speed, voltage, idle time, field programmable gate array (FPGA) logic, or combination thereof, of the processing system.

24. The method of claim 17, wherein the applying includes modifying the processing system or transmitting at least one message to the processing system which, in turn, is causes the processing system to apply the variations identified.

25. The method of claim 17, further comprising employing at least one monitored parameter to determine the respective effects, wherein the respective effects are associated with memory utilization, temperature, throughput, latency, power, quality of service (QoS), memory access, or combination thereof.

26. The method of claim 17, further comprising:
producing at least one monitored parameter by monitoring at least one parameter associated with the processing, periodically, over time, by a monitoring circuit; and
employing the at least one monitored parameter to determine the respective effects.

27. The method of claim 17, wherein the variations identified include populations of respective trial variations and wherein the method further comprises:
employing a genetic method to evolve the populations on a population-by-population basis;
transmitting, on the population-by-population basis, the populations evolved to a system controller; and
wherein the applying includes applying the respective trial variations of the populations evolved to the processing system by the system controller on a trial- variation-by-trial-variation basis.

28. The method of claim 27, further comprising:
determining the respective effects by a neural network based on at least one monitored parameter of the processing system, the respective effects resulting from applying the respective trial variations to the processing system;
assigning, by the neural network, respective rankings to the respective trial variations based on the respective effects determined and the at least one goal; and
transmitting, by the neural network, the respective rankings on the trial-variation-by-trial-variation basis to the system controller.

29. The method of claim 28, further comprising:
determining respective ranked populations of the populations, the respective ranked populations including respective rankings of the respective trial variations; and
evolving, by the genetic method, a present population of the populations into a next population of the populations based on a given respective ranked population of the respective ranked populations, the given respective ranked population corresponding to the present population.

30. The method of claim 29, wherein the variations identified include populations of respective trial variations, wherein the evolving includes evolving the populations on a population-by-population basis, wherein the given variation is a given trial variation included, consistently, by the genetic method in the populations evolved, and wherein the given variation is converged on by the genetic method based on a respective ranking assigned thereto by the neural network.

31. A system comprising:
means for identifying variations for altering processing of a processing system to meet at least one goal;
means for applying the variations identified to the processing system;
means for determining respective effects of the variations identified and applied; and
means for converging on a given variation of the variations identified and applied, the converging based on the respective effects determined, the given variation enabling the at least one goal to be met.

32. A non-transitory computer-readable medium having encoded thereon a sequence of instructions which, when loaded and executed by at least one processor, causes the at least one processor to:
identify variations for altering processing of a processing system to meet at least one goal;
apply the variations identified to the processing system;
determine respective effects of the variations identified and applied; and
converge on a given variation of the variations identified and applied, the converging based on the respective effects determined, the given variation enabling the at least one goal to be met.
